(19) United States
(12) Patent Application Publication
(10) Pub. No.: US 2026/0173842 A1
(43) Pub. Date: Jun. 18, 2026

(54) Method for Producing a Through-semiconductor Connection

(71) Applicant: IMEC VZW, Leuven (BE)

(72) Inventors: Liesbeth Witters, Lubbeek (BE); Takushi Shigetoshi, Leuven (BE); Eric Beyne, Heverlee (BE)

(21) Appl. No.: 19/353,993

(22) Filed: Oct. 9, 2025

(30) Foreign Application Priority Data
Oct. 21, 2024 (EP) 24207810.3

(51) Int. Cl. H10W 20/20; H10D 84/83; H10W 20/00

(52) U.S. Cl. CPC H10W 20/2134; H10W 20/0234; H10W 20/0265; H10W 20/215; H10D 84/832

(57) ABSTRACT

A thinned semiconductor substrate is provided. The front end of line portion on the front side includes conductive structures of the thinned substrate, which may be contacted by connections through the substrate. An opening is etched from the back to be filled with a conductive material. The bottom of the opening overlaps the end surface of the conductive structure to be contacted and further overlaps a portion of semiconductor material of the substrate. Etching of the opening continues beyond the end surface into the semiconductor portion(s), to create cavities. A first dielectric layer is formed on the sidewalls and bottom of the opening. The cavities are filled with the material of the first layer. This material is removed except in the cavities. The dielectric-filled cavities inhibit the formation of shorts between the through-connection obtained by filling the opening and the semiconductor material of the substrate.

### CROSS-REFERENCE TO RELATED APPLICATIONS

The present application is a non-provisional patent application claiming priority to European Patent Application No. 24207810.3, filed Oct. 21, 2024, the contents of which are hereby incorporated by reference.

### FIELD OF THE DISCLOSURE

The present disclosure is related to semiconductor processing, as applied to the production of semiconductor components such as integrated circuit (IC) chips. The disclosure relates to connections which provide the conduction of current between the front and back sides of the component.

### BACKGROUND

Multiple semiconductor components such as ICs are processed simultaneously on a large semiconductor wafer, usually a silicon wafer. Due to congestion of routing on the wafer frontside for advanced technological nodes, part of the functionality can be moved from the wafer frontside to the wafer backside. This allows for a continued density scaling of device structures. An example is the power delivery network that is moved to the backside of the wafer.

Making a through wafer connection between the frontside and the backside design involves bonding the wafer to a carrier substrate and thinning the wafer from the back side prior to backside layer patterning. If the initial wafer substrate is not fully removed during thinning, connections may be made through the thinned wafer material, for connecting devices at the front side to the back side of the eventual IC. Local through-connections are referred to as “substrate vias” (SV) or “through substrate vias” (TSVs). These are local via connections from the back side of a substrate (such as the thinned wafer) and contact a conductive structure at the front side of the substrate. Other through-connections are elongate structures such as power rails or conductive lines. The structures at the front side may also be local via connections, or elongate structures such as buried power rails.

In most cases, the connecting features may be electrically isolated from the thinned wafer material, typically using a dielectric liner. Highest densities may be achieved using tip-to-tip connections between frontside features (e.g., a buried power rail or highly doped epitaxial source or drain of the transistors) and the connecting features (e.g., TSV or metal line). For high density designs, the overlay specifications for backside to frontside patterns may be (e.g., very) small and at the limit of what a scanner can correct for. This potentially limits the densities that can be achieved.

### SUMMARY

This disclosure is related to a method and to a semiconductor component. According to the disclosure, a thinned semiconductor substrate is provided having a front end of line (FEOL) (e.g., portion on its front side. The FEOL (e.g., portion) may include conductive structures at the front side of the thinned substrate, such as buried power rails or via connections which may be contacted by connections through the substrate. For producing such a through-connection, an opening is etched from the back of the thinned substrate, and may be filled with a conductive material. The bottom of the opening overlaps (e.g., at least partially) the end surface of the conductive structure to be contacted, and further overlaps one or more portions of semiconductor material of the substrate. This (e.g., overlap) may be due to a degree of misalignment of the opening relative to the end surface, or to the dimensions of the opening relative to the end surface, or to the orientation of the opening relative to semiconductor features on the substrate surface, such as semiconductor fins, or to a combination of these circumstances. According to the disclosure, etching of the opening continues beyond the end surface into the semiconductor portion(s), to thereby create one or more cavities, at least one cavity being in the vicinity of the end surface.

A first dielectric layer is formed on the sidewalls and bottom of the opening, so that the cavity or cavities are filled with the material of the first layer. This material is then removed by an isotropic etch, so that the material may be removed everywhere except in the cavity or cavities. If useful (e.g., necessary), a second dielectric layer may be formed as a liner on the sidewalls and bottom of the opening, to be opened up at the bottom by an anisotropic etch to thereby expose the end surface. The dielectric of the first layer, however, may remain in the cavity or cavities. These dielectric-filled cavities thereby inhibit the formation of shorts between the (e.g., eventual) through-connection obtained by filling the opening, and the semiconductor material of the substrate.

The disclosure thereby allows a larger degree of misalignment, providing (e.g., enabling) higher densities in the layer designs on the front and back side of the substrate. For larger through-connections, the dielectric-filled cavities may mitigate stress in the vicinity of the connection.

The disclosure is related to a method for producing an electrical connection through a thinned semiconductor substrate. The substrate includes a bulk portion having a front side and a back side, wherein multiple semiconductor devices at least partly formed of semiconductor material of the substrate are located on the front side. The devices may be part of a front end of line portion. The front end of line portion may further comprise conductive structures which are part of or connected to one or more of the semiconductor devices. The conductive structures having an end surface may be contacted by the electrical connection. The method includes producing the front end of line portion on the front side of an initial substrate and thinning the initial substrate from the back side, to thereby obtain the thinned substrate.

The method thereafter may comprise a plurality of (e.g., consecutively applied) steps. The steps may include producing an opening through the back side of the thinned substrate, by an etch process that is selective with respect to the end surface of the conductive structure or with respect to a dielectric layer isolating the conductive structure from the material of the substrate. The bottom of the opening may overlap at least partially the end surface of the conductive structure and/or one or more portions of semiconductor material of the substrate, and the etch process may continue beyond the end surface into the one or more semiconductor portions, so that at least one cavity is formed. The bottom of the opening may comprise a first portion at least partially overlapping the end surface of the conductive structure and a second portion provided (e.g., defined) by the bottom of the cavity or cavities, wherein material of the substrate is exposed in the second portion of the bottom of the opening. The steps may further include depositing a first dielectric layer on the bottom and on the sidewalls of the opening. The thickness of the layer is such that the at least one cavity is (e.g., completely) filled with the material of the first dielectric layer. The steps also may include partially removing the first dielectric layer by an isotropic etch process configured to thin or completely remove the first dielectric layer on the sidewalls of the opening. The material of the first dielectric layer is thinned or removed from the first part of the bottom of the opening but maintained in the at least one cavity, to thereby create one or more dielectric-filled cavities. Either using the thinned first dielectric layer as a dielectric liner covering the sidewalls of the opening and the first part of the bottom of the opening, or if the first dielectric layer is fully removed from the sidewalls and first part of the bottom of the opening, the steps may include depositing a second dielectric layer to serve as the dielectric liner. Also, the steps may include, by an anisotropic etch, exposing the end surface of the conductive structure, while maintaining the dielectric liner on the sidewalls of the opening and while maintaining the material of the first dielectric layer in the at least one cavity. The steps also may include filling the opening with an electrically conductive material, to thereby form the electrical connection through the thinned substrate, so that the connection is isolated from the material of the substrate by the dielectric liner and by the dielectric-filled cavity or cavities.

According to an example embodiment, the end surface of the conductive structure is buried in the bulk portion of the substrate at the front side thereof, and the opening is misaligned and/or wider with respect to the width of the conductive structure in a given direction, so that the at least one cavity is formed in the bulk portion of the substrate. According to example embodiments, the conductive structure may be a buried power rail or a source or drain of a transistor.

According to an example embodiment, the end surface of the conductive structure is in close proximity to a semiconductor portion of a semiconductor device located on the front side of the bulk portion of the substrate, and the at least one cavity is formed in the semiconductor portion of the device.

According to an example embodiment, the opening is wider and/or misaligned with respect to the width of the conductive structure, as measured in a given direction.

According to an example embodiment, the semiconductor portion of the device is a fin-shaped portion extending in a longitudinal direction, wherein the given direction is perpendicular to the longitudinal direction of the fin-shaped portion.

According to an example embodiment, the semiconductor portion of the device is a fin-shaped portion extending in a longitudinal direction, wherein the opening is an elongate opening oriented transversely with respect to the longitudinal direction and wherein the length of the opening fully overlaps the width of the fin-shaped portion. According to example embodiments, the conductive structure is a via connection.

According to an example embodiment, the electrical connection through the substrate is a through substrate via, a conductive line, or a power rail.

According to an example embodiment, the first dielectric layer is a (e.g., uniform) layer formed of a single dielectric material.

According to an example embodiment, the first dielectric layer is a stack of a first and second dielectric layer, wherein the second layer is removable selectively with respect to the first layer, by the isotropic etch process.

The disclosure is also related to a semiconductor component comprising a semiconductor substrate comprising a bulk portion having a front side and a back side, wherein the substrate comprises a front end of line portion on the front side of the bulk portion. The front end of line portion includes electrically conductive structures which are part of or connected to semiconductor devices within the front end of line portion. The component includes at least one electrical connection passing through the substrate from the back side of the substrate and contacting an end surface of one of the conductive structures while being isolated from the material of the substrate by a dielectric liner, and by at least one dielectric-filled cavity in the vicinity of the end surface of the conductive structure.

According to an example embodiment of the semiconductor component, the conductive structure is one of a buried power rail, a source or drain of a transistor, and/or a via connection.

According to an example embodiment of the semiconductor component, the electrical connection through the substrate is a through substrate via, a conductive line, and/or a power rail.

### BRIEF DESCRIPTION OF THE FIGURES

The above, as well as additional, features will be better understood through the following illustrative and non-limiting detailed description of example embodiments, with reference to the appended drawings.

FIG. 1 shows a (e.g., small) section of a front end of line layout as processed on the front side of a semiconductor wafer.

FIG. 2 shows the face-down bonding of the processed wafer to a carrier wafer, prior to back side thinning of the processed wafer.

FIG. 3 shows the bonded semiconductor wafer after back side thinning.

FIGS. 4A, 4B, 4C, 4D, 4E, 4F, and 4G illustrate the production of a through substrate via (TSV) for contacting a buried power rail, wherein the TSV is aligned to the buried rail.

FIG. 5 shows the maximum amount of misalignment that is allowable, without creating a short between the TSV and the wafer material.

FIG. 6 shows a larger misalignment and the unwanted consequence thereof, which is the creation of a short between the TSV and the wafer material.

FIGS. 7A, 7B, 7C, 7D, and 7E illustrate a first embodiment of the method of the disclosure for forming a TSV contacting a buried power rail in a via opening that is misaligned to the rail.

FIGS. 8A, 8B, 8C, 8D, and 8E illustrate a second embodiment.

FIGS. 9A, 9B, 9C, 9D, 9E, 9F, 9G, and 9H illustrate the application of the disclosure for contacting the source of a nano-sheet transistor by a TSV that is misaligned to the source.

FIGS. 10A, 10B, 10C, and 10D illustrate an example embodiment wherein the thick dielectric is a stack of a first and second dielectric layer.

FIGS. 11A, 11B, 11C, 11D, 11E, and 11F illustrate the application of the disclosure for forming a TSV contacting a buried power rail, wherein the TSV is misaligned to the buried rail and wider than the rail.

FIG. 12 shows another front end of line layout processed on the front side a semiconductor wafer, suitable for applying thereto another embodiment of the method of the disclosure.

FIG. 13 shows the wafer of FIG. 12 after bonding to a carrier and thinning the bulk portion of the wafer.

FIGS. 14A, 14B, 14C, 14D, 14E, and 14F illustrate an example embodiment of the disclosure, applied to the configuration shown in FIG. 13.

FIGS. 15A, 15B, 15C, and 15D illustrate a variant of the embodiment of FIGS. 14A-14F, wherein the full width of a semiconductor fin is covered by the width of a through-connection.

FIGS. 16A, 16B, 16C, 16D, 16E, 16F, and 16G illustrate an example embodiment wherein an elongate through-connection is formed to contact a via connection, and wherein the through-connection is oriented perpendicularly to the orientation of the fins at the front side.

The figures are schematic, not necessarily to scale, and generally show parts which elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

The problem set out in the background will first be illustrated on the basis of a specific exemplary configuration, after which the solution provided by the disclosure is demonstrated on the same and other configurations. Throughout the present disclosure, the term “conductive” is to be understood as “electrically conductive.”

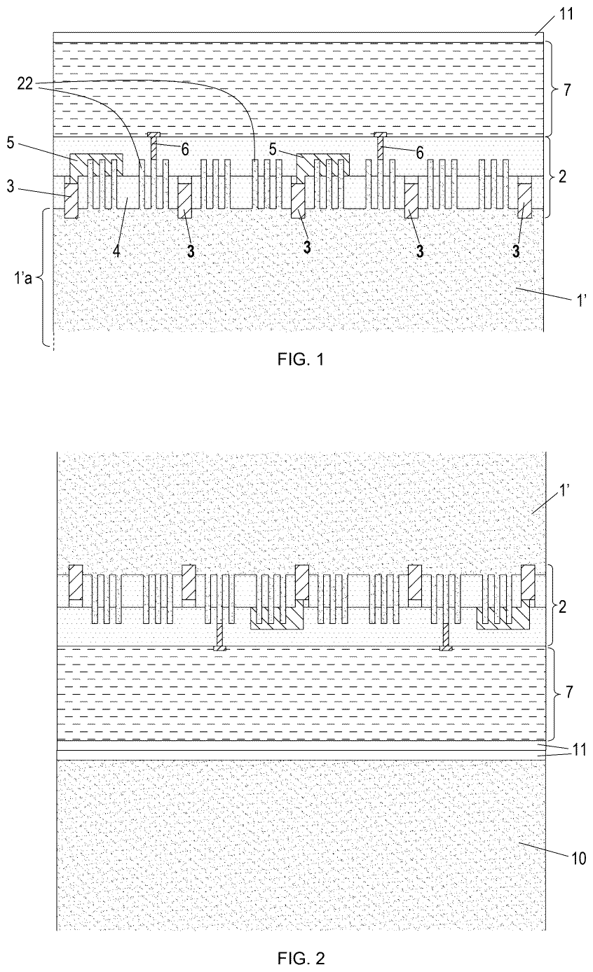

FIG. 1 is a schematic and simplified cross-section of a small portion of a semiconductor substrate 1′, which may be a standard silicon process wafer, on the front side of which a number of processing steps have been performed, which have created multiple devices in a front end of line (FEOL) portion 2 of an electronic component, such as an integrated circuit. In the example, these include fin-based transistors whose source areas are connected to buried power rails 3. The transistors are processed on silicon fins 22 (e.g., integral) with the bulk portion 1′a of the substrate 1′, and extend upward from the bulk portion. The transistors are therefore at least partially formed of the semiconductor material of the substrate 1′. The power rails 3 are longitudinal metal structures partly buried in the bulk portion 1′a, and partly in the dielectric material 4, which may be referred to as STI (shallow trench isolation) dielectric, formed between the fins 22. The width of the rails 3 may be in the order of a few tens of nanometers, and the rails may extend over (e.g., relatively long distances) in the longitudinal direction of the fins 22. The rails 3 are isolated from the substrate material by a dielectric liner. Local interconnects 5 couple the transistors to the rails 3 at dedicated locations. Further connections 6 couple the transistors to a multilayer interconnect structure 7, also referred to as the back end of line (BEOL) portion, illustrated in (e.g., a simplified fashion in) the drawing. The aim is to access the buried power rails 3 from the backside in order to connect the rails to a back side power delivery network.

In order to realize this, the substrate is first bonded face down to a carrier substrate 10, as illustrated in FIG. 2. The carrier may be a temporary carrier, to be released at a later stage, or it can be another process wafer comprising FEOL and BEOL portions, to which the substrate is (e.g., permanently) bonded to form a stacked device configuration.

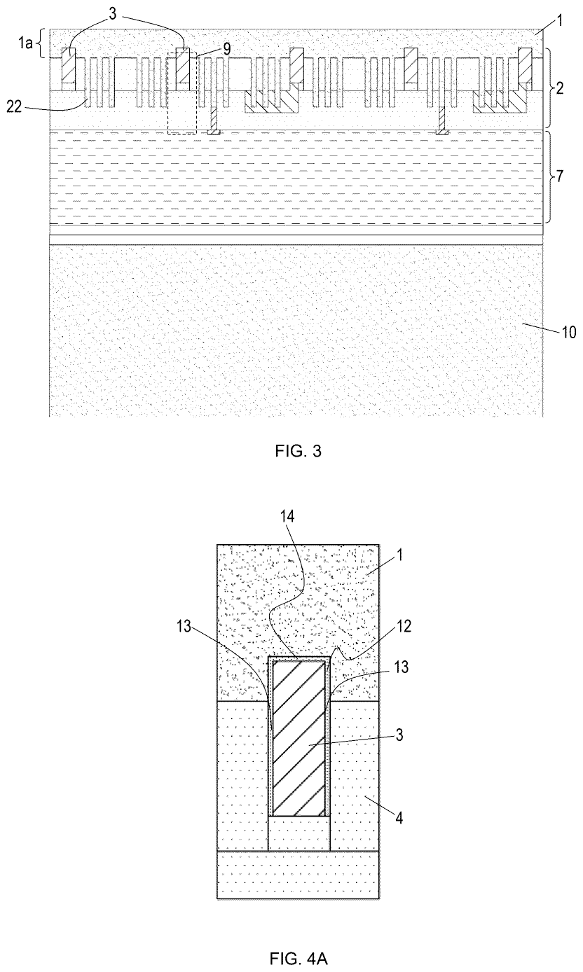

The carrier 10 and the substrate 1′are provided with bonding layers 11 which provide forming a bond between these substrates. Then the bulk portion 1′a is thinned from the back side, which may be done by grinding techniques and CMP (chemical mechanical polishing), that may end with a wet etch step, stopped by an etch stop layer incorporated in the substrate, to provide (e.g., enable) thinning to a (e.g., very) low thickness, in the order of 1 micrometer or less. The result of the substrate thinning step is illustrated in FIG. 3, showing the thinned substrate 1, comprising bulk portion 1a, with fins 22 extending from the bulk portion at the front side thereof.

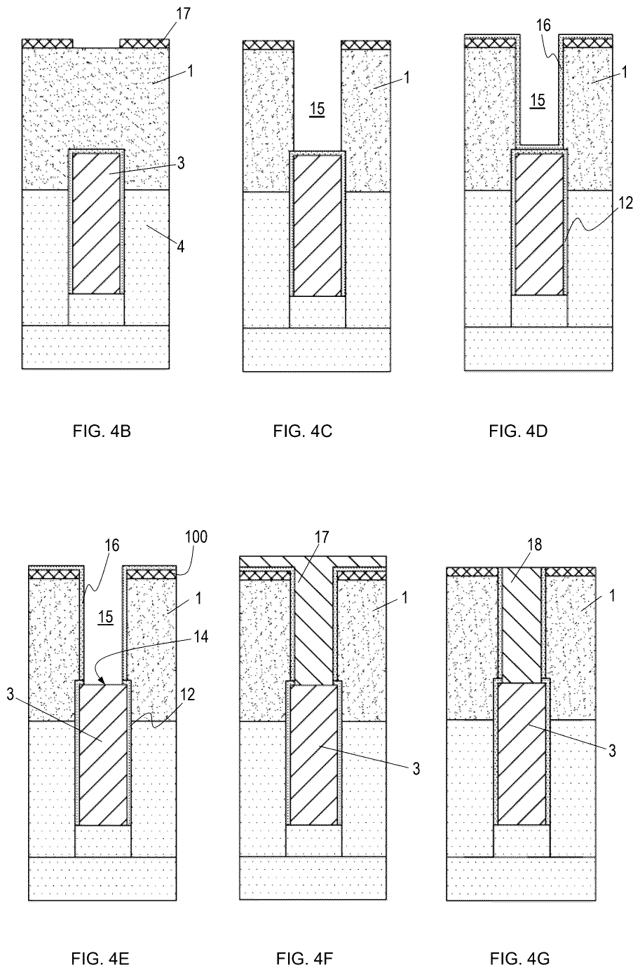

FIG. 4A shows an enlarged image of the rectangle 9 in FIG. 3 including one of the buried power rails 3, also showing the dielectric layer 12, hereafter referred to as a liner, that isolates the rail from the substrate material 1. The rail 3 is a conductive structure extending in a longitudinal direction and provided (e.g., defined) by two sidewalls 13 parallel to the longitudinal direction and by an end surface 14 buried in the bulk portion 1a of the semiconductor substrate 1. The end surface 14 of the rail is to be contacted by a through substrate via (TSV) through the thinned substrate 1. The term TSV is used herein for (e.g., all) local via connections passing through the thinned substrate from the back side. Another possible term for these connections is the “substrate via” (SV). FIGS. 4B, 4C, 4D, 4E, 4F, and 4G illustrate the (e.g., required) steps when there is a (e.g., perfect) alignment between the TSV and the buried rail, for a TSV that is narrower than the width of the rail. In the drawings, the TSV may (e.g., is supposed to) have a constant cross-section, but TSVs may be narrower at the bottom than at the top. Within the present context, the “width of the TSV” is to be understood as the width at the bottom of the TSV, as measured perpendicularly to the structure that is to be contacted (such as, in this case, the buried rail 3). In a cross-section parallel to the substrate 1, the TSV may have a round shape, a square shape, or a rectangular shape, extending substantially parallel to the rail over a short distance relative to the length of the rail. When the distance is longer, the through-connection is no longer referred to as an TSV, but rather is referred to as a line-shaped through-connection or conductive line running parallel to the longitudinal direction of the rail or equivalent conductive structure. The method as described hereinafter is, however, applicable without changes to TSVs as well as to longer conductive lines.

With reference to FIG. 4B, a dielectric hardmask layer 17, for example a SiN or a SiO₂ layer, is formed on the surface of the thinned substrate 1, and the hardmask layer is patterned to form an opening therein, with (e.g., perfect) alignment to the buried rail 3. As illustrated in FIG. 4C, a via opening 15 is then formed by anisotropically etching the substrate material relative to the patterned hardmask layer 17 stopping on the liner 12 of the buried rail 3.

A dielectric liner 16 is formed on the sidewalls (FIG. 4D) and bottom of the via opening 15, and subsequently the liners 16 and 12 are removed from the bottom of the via opening 15 by an anisotropic etch process (FIG. 4E), thereby exposing the end surface 14 of the rail 3. The liner 16 may be formed, for example, of silicon oxide, deposited by atomic layer deposition.

The process for removing the liners 16 and 12 from the bottom of the via opening 15 may be a plasma etch, that preserves the layers on the sidewalls while removing the horizontal layers 16, 12 on the bottom of the via opening 15 and on the end surface 14 of the buried rail 3. For example, the plasma etch method as described in patent publication document EP3035369 may be used, wherein a polymer layer is formed on the sidewalls and the upper surface of the liner 16, while the liner 16 and the liner 12 on the end surface 14 of the rails are removed at the bottom of the via opening. Afterwards, the polymer layer is also removed selectively with respect to the remaining liner 16, resulting in the image shown in FIG. 4E. After this, the via opening 15 is filled with an electrically conductive material, such as a metal, as illustrated in FIG. 4F. This may, for example, be tungsten, ruthenium, molybdenum, or cobalt, formed by atomic layer deposition (ALD). This is followed by planarization to remove the metal and the liner material from the surface of the thinned semiconductor substrate 1. Alternatively, the liner material may be maintained on the surface of the thinned substrate. The result is shown in FIG. 4G of a (e.g., perfectly) aligned through substrate via 18 contacting the buried rail 3. The TSV 18 is ready to be contacted by further conductors within layers to be processed on the planarized back side of the thinned substrate 1. The hardmask 17 remains and may form an isolation layer between the substrate 1 and further conductors processed on the back side thereof.

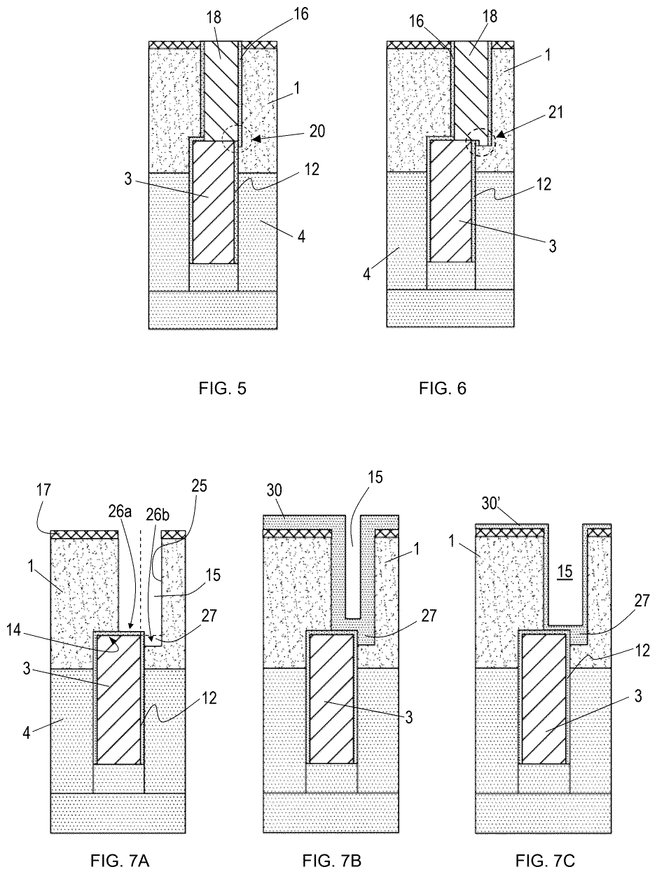

The (e.g., perfect) alignment is however not guaranteed, and misalignment between the via opening 15 and the rail 3 may occur. FIG. 5 illustrates the maximum allowable misalignment, wherein the overlapping liners in area 20 are still isolating the connected rail 3 and TSV 18 from the substrate material 1. However, when the misalignment is larger, the situation as shown in FIG. 6 occurs, wherein part of the exposed bottom of the via opening 15 is in direct contact with the bulk of the substrate 1, and the resulting TSV 18 therefore connects to the substrate in area 21, i.e. a short is formed between the TSV 18 and the substrate 1 at this location.

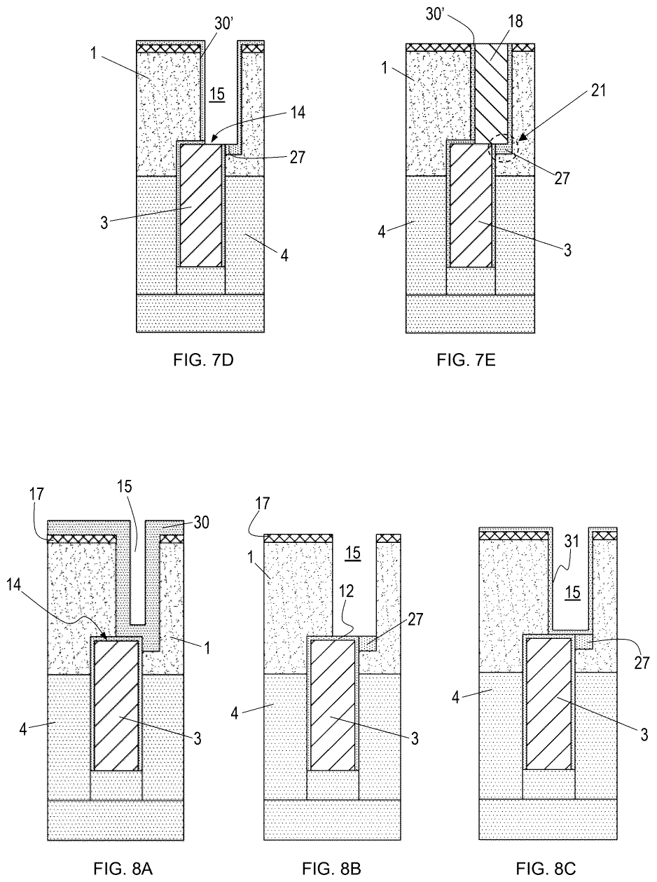

The present disclosure provides a solution to the occurrence of shorts as described above. FIG. 7A shows a misaligned via opening 15 that may lead to the short in area 21 as described hereabove. The misalignment is such that (as seen in the cross-section), one side 25 of the via opening 15 lies outside the width of the buried rail 3. This means that a first part 26a of the bottom of the via opening 15 overlaps the end surface 14 of the rail 3, while a second part 26b lies adjacent the end surface 14. Because of the degree of misalignment and because the etch process for forming the via opening 15 continues down to a given depth beyond the end surface 14 of the buried rail, the second part 26b is deeper than the first part 26a and thereby forms the bottom of a cavity 27 lying adjacent the end surface 14 of the buried rail 3.

A thick dielectric layer 30 is now formed on the bottom and the sidewalls of the via opening 15, as shown in FIG. 7B. The thickness of the dielectric layer 30 is (e.g., sufficient) to fill the cavity 27 with dielectric material, without however filling the via opening 15 completely. The dielectric material may for example be silicon oxide, deposited by atomic layer deposition which provides (e.g., ensures) that the cavity 27 is fully filled. In the illustrated embodiment, the layer 30 is a (e.g., uniform) layer formed of a single dielectric material, however, layer 30 could also be formed of multiple stacked dielectric layers of different materials, as provided later in this description.

Then an isotropic etch process is performed on the dielectric layer 30, i.e., the material is removed at the same rate in one or more of a plurality of (e.g., all) directions. In the embodiment shown, this etch process is stopped when (e.g., only) a thin dielectric layer 30′ remains on the sidewalls of the via opening 15, and on the first part 26a of the bottom of the opening, while the cavity 27 remains filled with the material of dielectric layer 30.

The thin remaining dielectric layer 30′is used as a liner for isolating the (e.g., eventual) TSV from the substrate 1, and may therefore be subjected to an anisotropic etch process, for removing the liner 30′from the first part 26a of the bottom of the opening 15 and for removing the liner 12 from the end surface 14 of the buried rail 3 in the part of the opening overlapping the end surface 14, to thereby expose the end surface 14. When these layers have been removed, there remains dielectric material in the cavity 27, as illustrated in FIG. 7D. Therefore, when the via opening 15 is filled with metal, the final TSV 18 is (e.g., effectively) isolated from the substrate 1 in area 21 by the dielectric-filled cavity 27 and by the liner 30′, as illustrated in FIG. 7E.

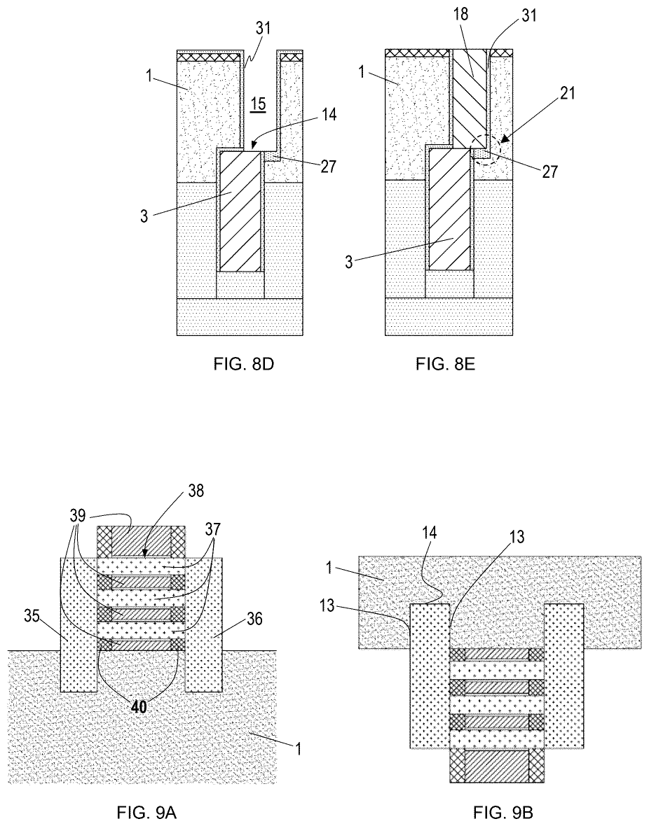

It may be challenging to control the isotropic etch process so that the correct liner thickness 30′ remains on the sidewalls and on the first part 26a of the bottom of the via opening 15. According to another embodiment illustrated in FIGS. 8A, 8B, 8C, 8D, and 8E, the isotropic etch continues until (e.g., all) the dielectric material of layer 30 is removed from the sidewalls and from the first part 26a of the bottom of the via opening 15, whilst remaining in the cavity 27. This is illustrated in FIGS. 8A and 8B. The hardmask layer 17 remains, i.e., in this embodiment, the isotropic etch is selective with respect to the hardmask material.

As shown in FIG. 8C, a second dielectric layer 31 is then deposited, this time having the thickness of a standard liner. The second layer 31 may be formed of the same material as the first dielectric layer 30 or of a different material. This liner 31 and the liner 12 on the end surface 14 are then subjected to the usual anisotropic etch, exposing thereby the end surface 14, but stopping before removing the material of the first layer 30 from the cavity 27 (see FIG. 8D). As shown in FIG. 8E, filling the via opening 15 then leads to a through substrate via 18 that is (e.g., effectively) isolated from the substrate 1 in the area 21, by the dielectric-filled cavity 27 and by the liner 31.

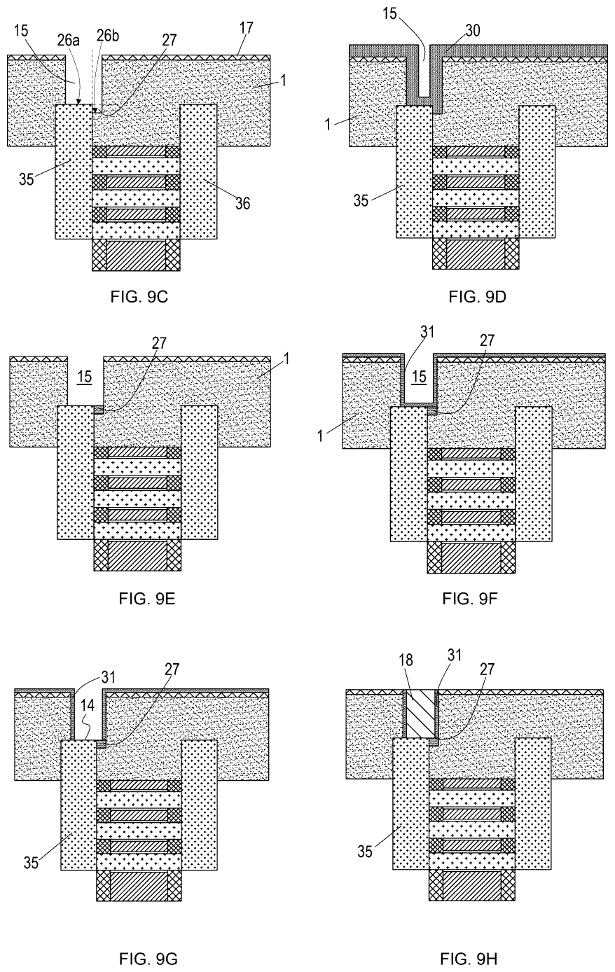

FIGS. 9A, 9B, 9C, 9D, 9E, 9F, 9G, and 9H illustrate the application of the disclosure for contacting the source or drain of a nano-sheet transistor. This device comprises two (e.g., heavily) doped regions, obtained by epitaxial growth, which serve as the source 35 and drain 36 of the transistor. The channel is formed by multiple thin semiconductor sheets 37, separated by a gate dielectric 38 and a metal gate 39 wrapped around the sheets. Dielectric spacers further separate the gate from the source and drain. The source and drain are doped by opposite type dopants as the substrate 1 and are therefore not isolated from the substrate by a dielectric liner. However, when contacting the source or drain from the back side by a through substrate via (TSV), the TSV again may (e.g., needs to) be isolated from the surrounding substrate material.

The substrate 1 is again attached face down to a carrier and thinned from the back side, as illustrated in FIG. 9B ((e.g., only) the device and the portion of thinned substrate 1 onto which it was processed is shown). The source 35 and drain 36 extend in the direction perpendicular to the drawing. Even though the length of the source and drain is shorter than the length of a buried rail, they can nevertheless be characterized, like the buried rail, as electrically conductive structures provided (e.g., defined) by two sidewalls 13 and an end surface 14 buried in the substrate 1. The aim is now to contact the source or drain by a TSV produced through the thinned substrate 1 from the back side.

As shown in FIG. 9C, a patterned hardmask 17 is formed and a via opening 15 is produced by lithography and etching. In the case shown, the via opening is misaligned to the width of the source 35. The etch process for producing the opening continues for a given depth beyond the end surface 14 of the source 35, so that the bottom of the opening has a first part 26a and a second part 26b that is deeper than the first part, i.e., forming a cavity 27 adjacent to the end surface 14 of the source 35. With reference to FIG. 9D, a thick first dielectric layer 30 is deposited, filling the cavity 27 and forming a thick layer on the bottom and sidewalls of the via opening 15, without completely filling the opening 15. As shown in FIG. 9E, the thick layer is removed everywhere except in the cavity 27, by an isotropic etch process. Then (shown in FIG. 9F), a second dielectric layer is deposited, forming a liner 31 on the first part 26a of the bottom of the via opening 15, on top of the dielectric-filled cavity 27 and on the sidewalls of the via opening 15. By an anisotropic etch, the liner 31 is removed from the bottom of the via opening 15, without however removing the material of the first dielectric layer 30 from the cavity 27 (see FIG. 9G). The end surface 14 of the source 35 is now exposed. As seen in FIG. 9H, filling the via opening with a metal then results in a TSV 18 that contacts the source 35, while being isolated from the substrate 1 by the dielectric-filled cavity 27 and by the liner 31.

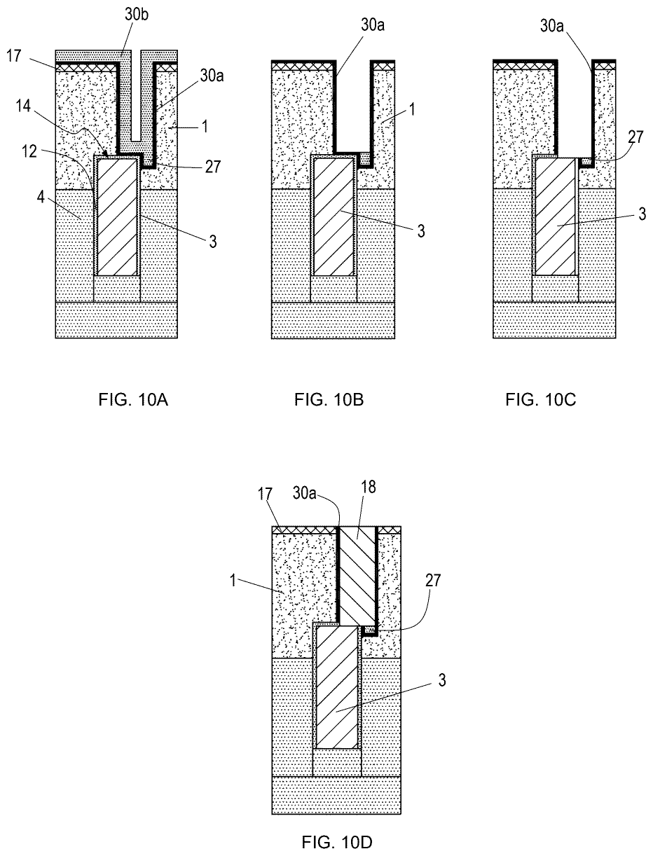

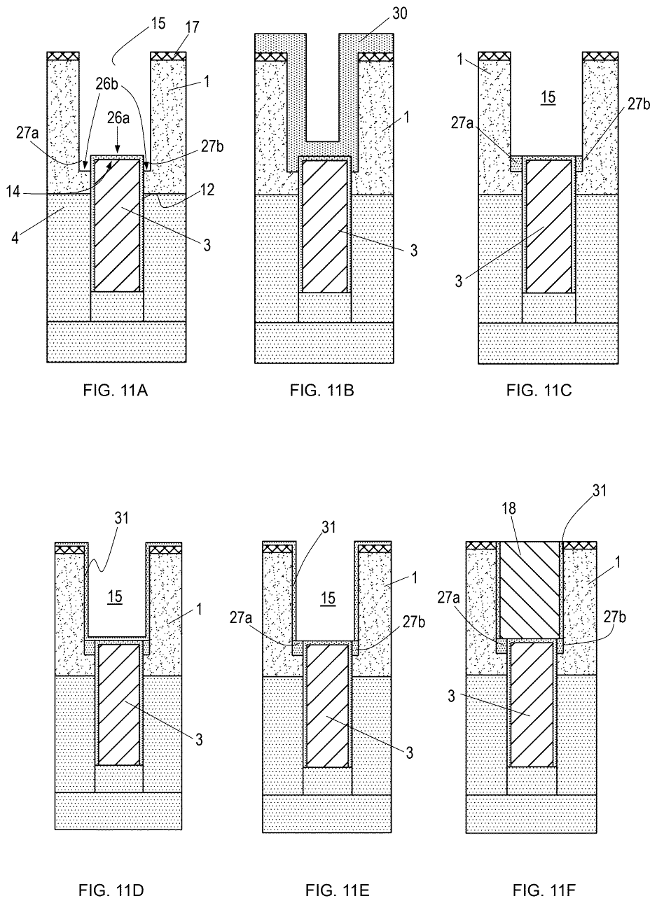

FIGS. 10A, 10B, 10C, and 10D illustrate wherein the thick first dielectric layer 30 is formed of a stack of a conformal thin first layer 30a and a thick second layer 30b. The first layer is conformal, in that it follows the topography provided (e.g., defined) by the cavity 27, i.e., the bottom and sidewalls of the cavity are lined with the first layer 30a. The second layer then fills the lined cavity and forms a thick layer on the sidewalls of the opening 15. The material of the second layer 30b is selectively removable by a selective etch process relative to the material of the first layer 30a. The first layer could for example be a layer of SiCO and the second a layer of SiO₂. As illustrated in FIG. 10B, this provides (e.g., enables) removing the second layer 30b by such a selective etch process, leaving (e.g., only) the first layer 30a, which can then be treated like a liner, as in the previous embodiments. Also, an additional liner may be added onto layer 30a to improve the isolation. The anisotropic etch of the liners 30a and 12 is illustrated in FIG. 10C, followed by the filling of the opening to form the TSV 18, illustrated in FIG. 10D. This embodiment is useful if the isotropic etch is not selective to the hardmask material of the hardmask layer 17 or exhibits insufficient etch selectivity to this material. The first layer 30a then protects the edges of the hardmask layer 17 around the opening 15.

The method may also be applicable when the TSV is wider than the buried rail to which it is to be connected. This is illustrated in FIGS. 11A, 11B, 11C, 11D, 11E, and 11F. As seen in FIG. 11A, the via opening 15 is slightly misaligned to the buried rail 3, thereby creating different-sized cavities 27A and 27B on both sides of the end surface 14 of the buried rail 3. The bottom of the two cavities combined now forms the second part 26b of the bottom of the opening 15, while the first part 26a is formed by the surface of the liner 12 covering the end surface 14 of the buried rail 3. The thick first dielectric layer 30 fills both cavities (FIG. 11B), and after the isotropic etch, (e.g., only) the cavities remain filled with dielectric (FIG. 11C). Then the second dielectric layer 31 is formed, forming a liner (FIG. 11D), which is then removed from the bottom of the via opening 15, together with the liner 12 on the rail's end surface 14, but without removing the material of the first dielectric layer from the cavities (FIG. 11E). As seen in FIG. 11F, the metal-fill step then leads to the TSV 18, (e.g., effectively) isolated from the surrounding substrate by the dielectric-filled cavities 27A and 27B and by the liner 31.

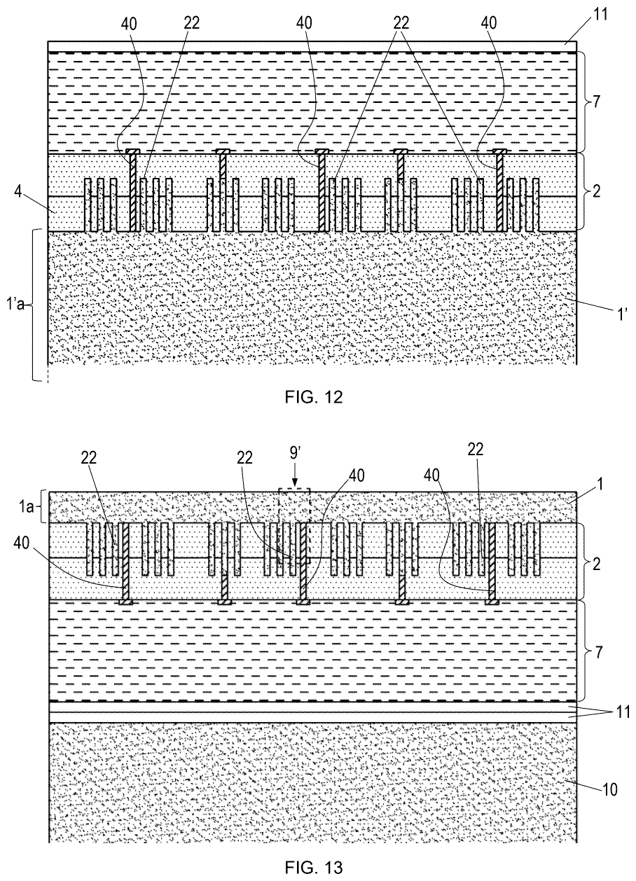

The disclosure is not limited to forming backside through-connections to structures which are buried in the bulk portion 1a of the thinned substrate at the front side thereof. The same method steps may be applicable when the end surface of the structure to be contacted is close to active semiconductor structures at the front of the substrate. Reference is made to FIG. 12, which shows another configuration comprising a FEOL portion 2 and BEOL portion 7 processed on a silicon substrate 1′. The FEOL portion now does not include buried power rails. Via connections 40 through the STI dielectric 4 are connected to the BEOL portion 7 and extend to the edge of the bulk portion 1′a of the substrate 1′. The via connections 40 are close to respective fins 22 onto which active devices such as transistors have been processed.

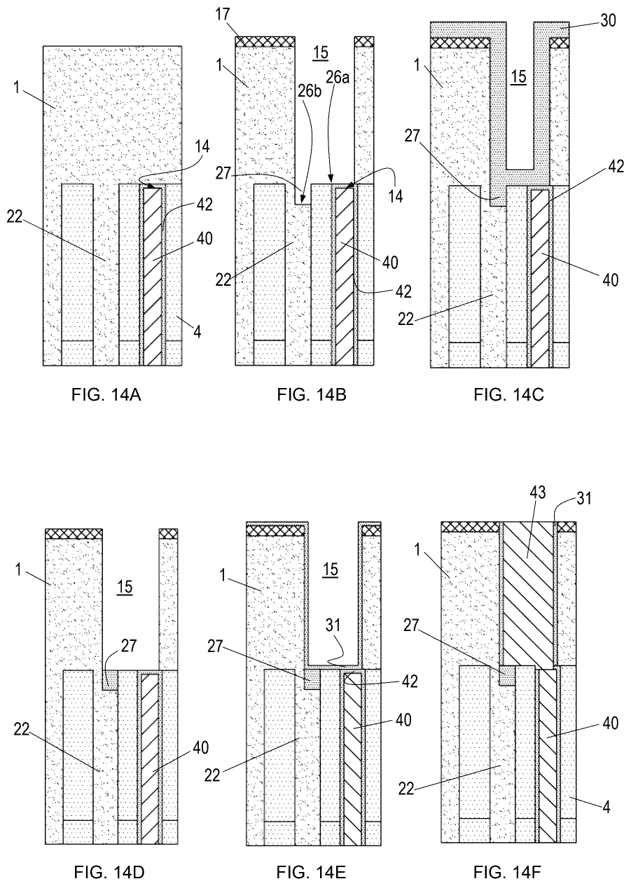

The aim is to thin the substrate 1′and to connect the via connections 40 to the back of the thinned substrate 1. FIG. 13 shows the substrate after bonding face down to a carrier substrate 10 (or to another process wafer) through bonding layers 11, and after thinning the substrate 1′from the back side, thereby obtaining thinned substrate 1 comprising bulk portion 1a. The rectangle 9′indicated in FIG. 13 is shown enlarged in FIG. 14A. In this enlarged view, it is shown that the via connection 40 is isolated by a dielectric layer (liner) 42, which separates the end surface 14 of the via connection 40 from the bulk portion 1a of the substrate 1. The liner 42 is optional within the broader scope of the disclosure, but the liner 42 may act as an etch stop layer in the subsequent method step, as described hereafter.

With reference to FIG. 14B, a hardmask layer 17 is formed on the thinned substrate and patterned, in order to produce an opening 15 through the back surface of the thinned substrate. In this embodiment, the opening 15 is an elongate trench, extending parallel to the fin 22 located closest to the via connection 40. The length of the trench 15 is considerably longer than the length of the via connection 40 in the longitudinal direction of the fin 22. The aim is to produce a power rail connecting the via connection 40, i.e., the “through-connection” in this case is a power rail.

The width of the opening 15 is misaligned to the width of the via connection 40. As in the previous embodiments, this misalignment is accidental and may not be the same across the substrate 1. In the particular case shown, the misalignment is such that the width of the bottom of the trench 15 overlaps the width of the fin 22, which can cause a short between the eventual through-connection and the fin 22, when various methods are applied. The disclosure obstructs the formation of a short as described hereafter.

The etch process for creating the trench 15 is selective with respect to the STI dielectric 4 and with respect to the dielectric material of the liner 42 and therefore stops on the end surfaces of these materials, but the etch continues into the base of the fin 22, thereby creating a cavity 27. This is similar to the previous embodiment, except that the cavity is not directly adjacent the end surface 14 but separated therefrom by a portion of the STI dielectric. The cavity is however in the vicinity of the end surface 14. As in the previous embodiment, the bottom of the trench 15 comprises a first portion 26a that overlaps the end surface 14 of the via connection 40, and a second portion 26b is provided (e.g., defined) by the bottom of the cavity 27.

After this, the same steps as described in relation to the previous embodiments may be performed. The thick dielectric layer 30 is formed on the bottom and sidewalls of the trench 15, filling the cavity 27 (FIG. 14C). The material of layer 30 is removed by isotropic etching, leaving the material (e.g., only) in the cavity (FIG. 14D). A dielectric liner 31 is deposited conformally (FIG. 14E), and subsequently this liner and the liner 42 are removed from the bottom of the trench by an anisotropic etch process. Finally, the trench is filled with metal, and the upper surface is planarized (FIG. 14F), resulting in a power rail 43 realized from the back of the thinned substrate that contacts the via connection 40 while being isolated from the fin 22 by the dielectric-filled cavity 27. By analogy with the embodiment shown in FIGS. 7A to 7E, it is also possible to thin the dielectric layer 30 on the sidewalls and bottom of the trench 15 and use the thinned layer 30 as the dielectric liner for isolating the eventual power rail 43 from the thinned substrate 1.

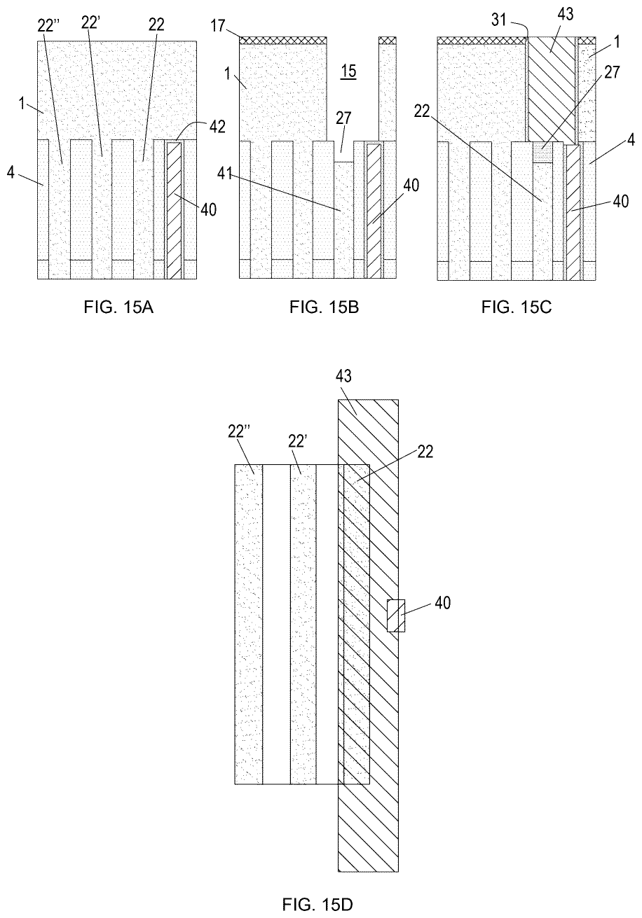

FIGS. 15A, 15B, and 15C illustrate a case wherein the width of the trench overlaps the full width of the nearest fin 22. The figures also show the two further fins 22′and 22″ at equidistant spacings next to fin 22. The method steps are the same as in the previous case, starting with the formation of the trench 15 (FIG. 15B) and resulting in the image shown in FIG. 15C. As shown, the cavity 27 now fully covers the base of the fin 22. FIG. 15D is a transparent and simplified top view (not including the dielectric liners), illustrating the position and in plane-dimensions of the via connection 40 and of the power rail 43, relative to the fins 22, 22′, and 22″.

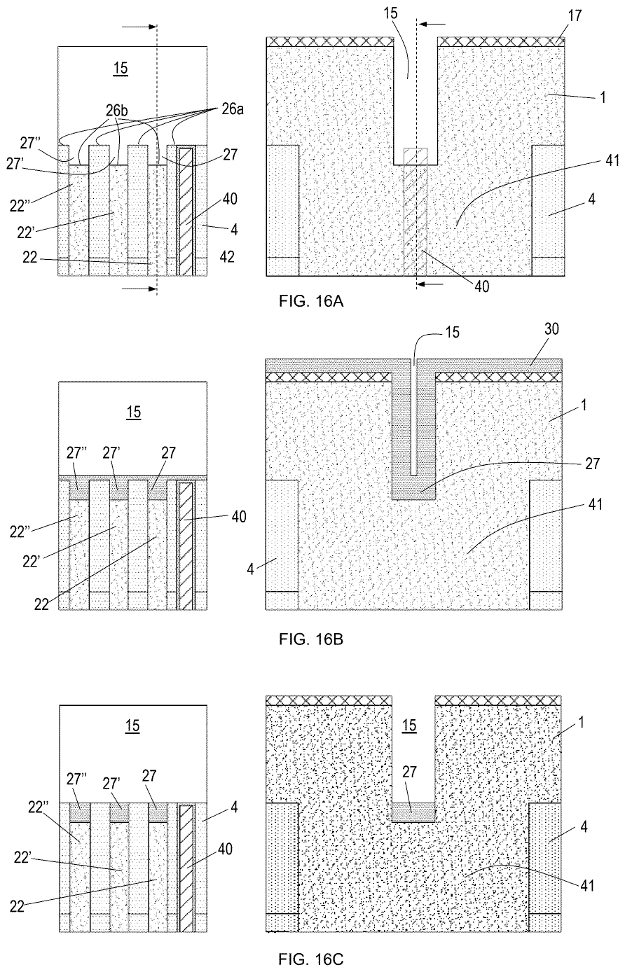

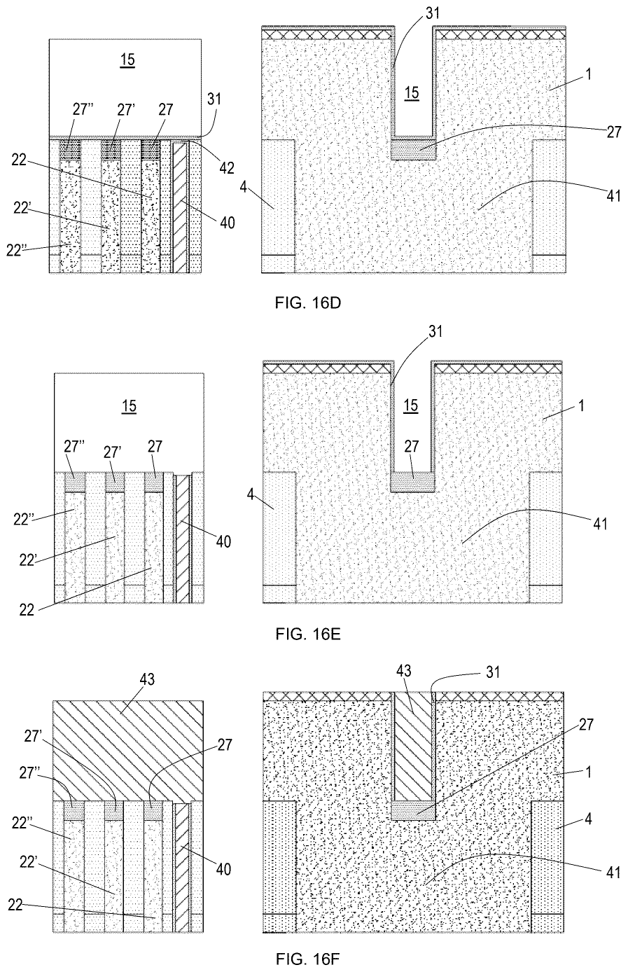

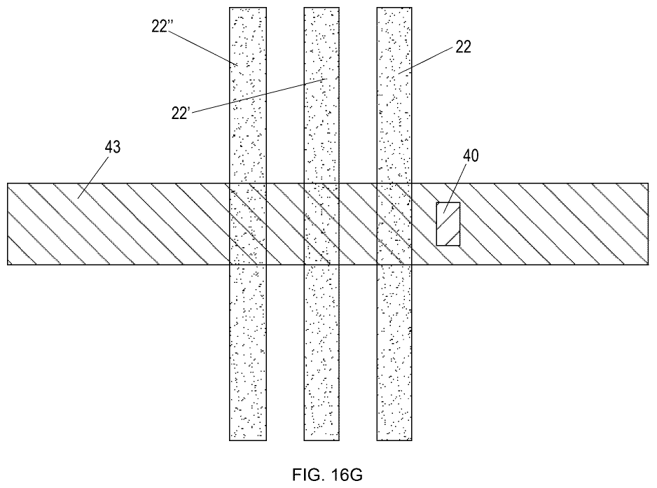

The method is furthermore applicable for contacting the via connection 40 by a power rail oriented transversally to the longitudinal direction of the fins 22. This is illustrated in FIGS. 16A, 16B, 16C, 16D, 16E, 16F, and 16G. A cross-section through the first fin 22 is now also illustrated. FIG. 16A illustrates the formation of the trench 15 oriented perpendicularly to the fins 22, 22′, and 22″. The left-hand side image shows (e.g., only) part of the trench 115. The width and depth of the trench 15 is visible in the cross-section through the first fin 22 (right-hand side image), which also illustrates the position of the via connection 40 relative to the trench 15. The trench 15 is (e.g., perfectly) aligned to the via connection 40. A degree of misalignment is possible, but the method is now also applicable in the illustrated (e.g., perfectly) aligned case, given the orientation of the trench, for obstructing the formation of shorts between the eventual rail and (e.g., all) the fins 22, 22′, 22″.

Etching of the trench 15 again continues beyond the end surfaces of the STI 4 and liner 42, which creates three cavities 27, 27′, 27″ which fully cover the base of the respective fins 22, 22′, 22″. The combined bottoms of the cavities provide (e.g., define) the second portion 26b of the bottom of the trench 15, while the combined higher-level portions provide (e.g., define) the first part 26a.

As shown in FIG. 16B, the thick dielectric layer 30 is deposited, filling the cavities and extending conformally on the bottom and sidewalls of the trench 15. Isotropic etching of layer 30 results, as shown in FIG. 16C, in the material of layer 30 remaining (e.g., only) in the cavities 27, 27′, 27″. With reference to FIG. 16D, a dielectric liner 31 is deposited, and thereafter removed from the bottom of the trench 15 by an anisotropic etch, removing also the liner 42 from the end surface of the via connection 40 thereby exposing the end surface, as illustrated in FIG. 16E. Then a metal is deposited and planarized, resulting in the transverse rail 43 connected to the via connection 40, and isolated from the fins 22, 22′, 22″ by respective dielectric-filled cavities 27, 27′, 27″, as illustrated in FIG. 16F.

FIG. 16G again shows a simplified transparent top view, illustrating the positions and in-plane dimensions of the rail 43 and the via connection 40, relative to the fins 22, 22′, 22″.

The disclosure is applicable for connecting various types of conductive structures at the front of the thinned substrate 1 by various types of through-connections produced from the back of the thinned substrate. For example, applying the same steps as described above, connections may be made between a via connection 40 at the front side and a TSV 18 through the substrate. The via connection 40 could also reach deeper into the bulk portion 1a of the substrate. In that case, one or more cavities 27 may be formed in the bulk portion, analogous to the embodiments shown in FIGS. 7 to 11.

A use of the disclosure, in the case of large through-connections through the thinned substrate, is that the dimensions of the dielectric-filled cavity or cavities 27 and the material for filling the cavity or cavities may be configured to decrease stress in the substrate 1 generated in the vicinity of the through-connection by frontside and backside conductors. This allows for reduction in size of a keep-out zone, i.e., a region around, for example a TSV, where the stress level is too high for producing semiconductor devices in the zone.

The method of the disclosure may be applied (e.g., simultaneously) to a large number of conductive structures, such as buried rails 3, source/drain areas 35, or via connections 40, distributed over a large substrate, such as a process wafer. The degree of misalignment may be different across the substrate, so the isolation through dielectric-filled cavities 27 may not be used (e.g., needed) in (e.g., every) opening 15 produced across the substrate. When the opening 15 is narrower than the structure and (e.g., perfectly) aligned to a buried rail 3 for example (as shown in FIGS. 4A to 4F), the method steps are performed as described above, but in that case no cavity 27 is formed adjacent the end surface 14 of the buried rail. The thick first dielectric layer 30 is deposited and subsequently this layer is thinned or completely removed by the isotropic etch. The disclosure thereby provides (e.g., enables) isolating (e.g., all) through-connections (e.g., TSVs, conductive lines or backside rails) (e.g., perfectly) from the substrate material, regardless of the width of the connections or of the degree of misalignment to the contacted structure.

A component produced by embodiments of the method of the disclosure can be recognized by the presence of a semiconductor substrate 1 and one or more dielectric-filled cavities 27, 27A, 27B, 27′, 27″, at least one of which lies in the vicinity of the end surface 14 of a conductive structure such as a buried rail 3 or via connection 40 at the front side of the substrate. The end surface 14 of the conductive structure is contacted by a through-connection, for example a TSV 18 or a power rail 43, through the substrate 1 of the component. The through-connection is isolated from the substrate material by a liner 31 and by the one or more dielectric-filled cavities.

While the disclosure has been illustrated and described in detail in the drawings and foregoing description, such illustration and description are to be considered illustrative or exemplary and not restrictive. Other variations to the disclosed embodiments can be understood and effected by those skilled in the art in practicing the claimed disclosure, from a study of the drawings, the disclosure, and the appended claims. In the claims, the word “comprising” does not exclude other elements or steps, and the indefinite article “a” or “an” does not exclude a plurality. The fact that certain measures are recited in mutually different dependent claims does not indicate that a combination of these measures cannot be used. Any reference signs in the claims should not be construed as limiting the scope.

What is claimed is:

1. A method for producing an electrical connection through a thinned semiconductor substrate,
the substrate comprising a bulk portion having a front side and a back side, wherein a plurality of semiconductor devices at least partly formed of semiconductor material of the substrate are on the front side,
wherein the semiconductor devices are part of a front end of line portion, the front end of line portion comprising conductive structures which are part of or connected to one or more of the semiconductor devices, and
an end surface of one of the conductive structures configured to be contacted by the electrical connection,
the method comprising:
producing the front end of line portion on the front side of an initial substrate and thinning the initial substrate from the back side to obtain the thinned substrate;
producing an opening through the back side of the thinned substrate, by an etch process that is selective with respect to the end surface of the conductive structure or with respect to a dielectric layer isolating the conductive structure from the material of the substrate, wherein a bottom of the opening overlaps at least partially the end surface of the conductive structure or one or more portions of semiconductor material of the substrate, and wherein the etch process continues beyond the end surface into the one or more semiconductor portions, such that at least one cavity is formed, and such that the bottom of the opening comprises a first portion at least partially overlapping the end surface of the conductive structure and a second portion provided by the bottom of the at least one cavity, wherein material of the substrate is exposed in the second portion of the bottom of the opening;
depositing a first dielectric layer on the bottom and on sidewalls of the opening, a thickness of the layer fills the at least one cavity with the material of the first dielectric layer;
partially removing the first dielectric layer by an isotropic etch process configured to thin or remove the first dielectric layer on the sidewalls of the opening, and wherein the material of the first dielectric layer is thinned or removed from a first part of the bottom of the opening, but maintained in the at least one cavity, to thereby create at least one dielectric-filled cavity;
depositing a second dielectric layer to serve as a dielectric liner on either the thinned first dielectric layer as a dielectric liner covering the sidewalls of the opening and the first part of the bottom of the opening, or if the first dielectric layer is removed from the sidewalls, the first part of the bottom of the opening;
by an anisotropic etch, exposing the end surface of the conductive structure, while maintaining the dielectric liner on the sidewalls of the opening and while maintaining the material of the first dielectric layer in the at least one cavity; and
filling the opening with an electrically conductive material, to thereby form the electrical connection through the thinned substrate, so that the electrical connection is isolated from the material of the substrate by the dielectric liner and by the at least one dielectric-filled cavity.

2. The method according to claim 1, wherein the end surface of the conductive structure is positioned in the bulk portion of the substrate at the front side thereof.

3. The method according to claim 2,
wherein the opening is misaligned or wider with respect to a width of the conductive structure in a given direction, so that the at least one cavity is formed in the bulk portion of the substrate.

4. The method according to claim 2, wherein the conductive structure is a buried power rail.

5. The method according to claim 2, wherein the conductive structure is a source or drain of a transistor.

6. The method according to claim 1, wherein the end surface of the conductive structure is in close proximity to a semiconductor portion of a semiconductor device located on the front side of the bulk portion of the substrate.

7. The method according to claim 6, wherein the at least one cavity is formed in the semiconductor portion of the device.

8. The method according to claim 7, wherein the opening is wider or misaligned with respect to a width of the conductive structure, as measured in a given direction.

9. The method according to claim 8, wherein the semiconductor portion of the device is a fin-shaped portion extending in a longitudinal direction.

10. The method according to claim 9, wherein the given direction is perpendicular to the longitudinal direction of the fin-shaped portion.

11. The method according to claim 9, wherein the opening is an elongate opening oriented transversely with respect to the longitudinal direction.

12. The method according to claim 11, wherein a length of the opening overlaps the width of the fin-shaped portion.

13. The method according to claim 12, wherein the conductive structure is a via connection.

14. The method according to claim 1, wherein the electrical connection through the substrate is a through substrate via, a conductive line, or a power rail.

15. The method according to claim 1, wherein the first dielectric layer is a substantially uniform layer formed of a single dielectric material.

16. The method according to claim 1, wherein the first dielectric layer is a stack of a first and second dielectric layer.

17. The method according to claim 16, wherein the second layer is selectively removable, with respect to the first layer, by the isotropic etch process.

18. A semiconductor component comprising:
a semiconductor substrate comprising a bulk portion having a front side and a back side, a front end of line portion on the front side of the bulk portion, the front end of line portion comprising electrically conductive structures which are part of or connected to a plurality of semiconductor devices within the front end of line portion; and
the semiconductor component comprises at least one electrical connection passing through the substrate from the back side of the substrate and contacting an end surface of one of the conductive structures while being isolated from a material of the substrate by a dielectric liner, and by at least one dielectric-filled cavity near the end surface of the conductive structure.

19. The component according to claim 18, wherein the conductive structure is a buried power rail, a source or drain of a transistor, or a via connection.

20. The component according to claim 18, wherein the electrical connection through the substrate is a through substrate via, a conductive line, or a power rail.
